(19) United States
(12) Patent Application Publication
(10) Pub. No.: US 2024/0213575 A1
(43) Pub. Date: Jun. 27, 2024

(54) COUNTERFLOW TEMPERATURE CONTROL DEVICE, BATTERY HOUSING FOR USING A TEMPERATURE CONTROL DEVICE

(71) Applicant: POLYTEC PLASTICS Germany GmbH & Co. KG, Lohne (DE)

(72) Inventors: Walter VAN GILST, Goes (NL); Jens HUCKLE, Graben-Neudorf (DE); Tobias BURKERT, Osnabrück (DE); Michael BUCK, D-49401 Damme (DE); Jorge SOARES, Wettringen (DE); Christoph LESON, Dinklage (DE); Christian BERDING, Lohne (DE)

(21) Appl. No.: 18/545,260

(22) Filed: Dec. 19, 2023

(30) Foreign Application Priority Data
Dec. 23, 2022 (DE) 10 2022 134 765.6

(51) Int. Cl. H01M 10/6554; F28F 3/12; H01M 10/63

(52) U.S. Cl. CPC H01M 10/6554; F28F 3/12; H01M 10/63

(57) ABSTRACT

A counterflow temperature control device for the temperature control of at least one object, comprising at least one first temperature control section including at least one first flow channel for a temperature control medium to flow through in a first flow direction from a first channel inflow to a first channel outflow along a first flow path, and at least one second temperature control section including at least one second flow channel for a second temperature control medium to flow therethrough in a second flow direction from a second channel inflow to an opposite second channel outflow along a second flow path, wherein the first flow direction is designed to extend substantially opposite to the second flow direction, and wherein the at least one first and second flow channels are in thermally conductive connection with the at least one object to be temperature-controlled.

### CROSS REFERENCE TO RELATED APPLICATIONS

This application claims priority to German Patent Application No. DE 10-2022-134-765.6, filed Dec. 12, 2022, incorporated herein by reference.

The present invention relates to a counterflow temperature control device for the controlling the temperature control of at least one object, a battery housing comprising a counterflow temperature control device, as well as to the use of a counterflow temperature control device.

The temperature of the accumulators during power consumption and output is essential for the service life and power output as well as for the safety of accumulators and rechargeable batteries. Devices and methods for active temperature control of accumulators and battery cells, respectively, are already known from prior art. The known concepts can be divided into two fundamentally different fields, namely convective temperature control and conductive temperature control of the battery cells.

With conductive cooling, at least one temperature control channel is formed, through which a temperature control medium flows. The at least one temperature control channel is in heat-conducting contact with the at least one object to be temperature-controlled, such as an accumulator. By selecting the temperature of the temperature control medium and the flow rate of the medium through the at least one temperature control channel, the object to be temperature-controlled can be brought to a desired temperature. Consequently, active cooling or heating can be provided.

In prior art, in the field of battery technology, for example in the field of electromobility, a plurality of individual battery cells are connected and interconnected, respectively, to form a large battery cell arrangement, for example in a battery housing. In said battery housings, a plural number of temperature control channels must also be formed in order to realize an active and as uniform as possible temperature control of the plurality of battery cells. The individual temperature control channels pass between, on or under the rows of individual battery cells. It is a disadvantage of the prior art devices that the temperature control medium increasingly adjusts to the temperature of the objects to be temperature-controlled as it flows through the temperature control channels, such that the temperature difference between the temperature control medium and the object to be temperature-controlled is smaller and the heat transfer therefore also decreases. Due to the adjustment of the temperature of the temperature control medium to the objects to be temperature-controlled along the flow path of the temperature control channel, it is necessary to supply the temperature control medium into the temperature control channels with a high temperature difference and/or a high volume flow to the objects to be temperature-controlled, in order to still achieve a suitable temperature control of the objects to be temperature-controlled in the region of the end of the temperature control channel.

Starting from the above-mentioned disadvantages of the prior art conductive temperature control device, it is an object of the present invention to provide an improved temperature control device for controlling the temperature of objects, which device can realize an improved heat transfer performance, while at the same time requiring lower partial effort, and realize an improved integration possibility.

According to a first aspect of the invention, the above object is achieved according to the invention with a counterflow temperature control device for controlling the temperature of at least one object. The counterflow temperature control device of the invention comprises at least one first temperature control section with at least one first flow channel having a channel cross section for the flow of a first temperature control medium in a first flow direction from a first channel inflow to a first channel outflow along a first flow path and at least one second temperature control section having a channel cross section for the flow of a second temperature control medium in a second flow direction from a second channel inflow to a second channel outflow along a second flow path. The first flow direction of the at least one first flow channel of the at least one first temperature control section is designed to extend substantially opposite to the second flow direction of the at least one second temperature control section. The ate least one first and second flow channels are in thermally conductive connection with at least one surface section to be temperature-controlled of the at least one object to be temperature-controlled.

The thermally conductive connection can be established between the at least one object to be temperature-controlled and the at least one first flow channel as well as the at least one second flow channel
either
by direct surface contact of the at least one first flow channel and the at least one second flow channel with the surface of the at least one object to be temperature-controlled, and/or
indirectly via a thermally conductive medium between the surface of the at least one object to be temperature-controlled and the surface or surfaces of the at least one first flow channel and the at least one second flow channel.

The thermally conductive medium may be formed by at least one thermally conductive gap-filling mass and/or by at least one thermally conductive layer which is preferably a thermally conductive film. According to the invention, the thermally conductive medium can also be formed by at least one thermally conductive plate, preferably formed by a metal sheet or a thermally conductive plate of a polymeric material. If at least two objects to be temperature-controlled are provided, the objects to be temperature-controlled can themselves use at least one object to be temperature-controlled as the thermally conductive medium and ensure thermal conduction between adjacent objects and the at least one first flow channel and the at least one second flow channel.

For thermal conduction, the at least one first or the at least one second flow channel can directly abut against a surface of the at least one object to be temperature-controlled or against a surface section of the at least one object to be temperature-controlled. However, it may also be provided according to the invention to arrange a thermally conductive element between the flow channels and the at least one object to be temperature-controlled or, for example, to introduce a heat-inducing or thermally conductive paste or liquid.

According to the invention, it may be provided that the at least one first temperature control section and the at least one second temperature control section are integrated into a single singular temperature control circuit and are fluidically connected in parallel to one another in the same. As an alternative, the at least one first and the at least one second temperature control section can be integrated in different temperature control circuits that are fluidly separate from each other.

In the framework of the present invention, the feature “fluidically connected in parallel” should be understood such that a temperature control medium flows through the at least one first and the at least one second temperature control section merely at the same time and in parallel to one another. According to the invention, this feature should not be misunderstood to mean that the flow direction of the at least one first and second temperature control section are necessarily all geometrically the same or necessarily have to extend in parallel. In this respect, the geometric direction of flow is entirely independent of the fluidic circuit or connection of the elements.

A liquid medium such as water, a polyhydric alcohol, glycol, an oil or preferably a heat transfer oil or a mixture of the aforementioned media can preferably be used as the temperature control medium. However, according to the invention, it can also be provided that a gaseous medium, such as air, can be used as the temperature control medium.

Furthermore, it may be provided that a plurality of first flow channels is formed, which, in terms of fluid technology, are connected to each other in parallel for the first temperature control medium to simultaneously flow through the plurality of first flow channels and/or wherein a plurality of second flow channels is formed which, in terms of fluid technology, are connected to each other in parallel for the second temperature control medium to simultaneously flow through the plurality of second flow channels.

According to the invention, the first and second temperature control media may be one and the same temperature control medium and therefore also belong to the same temperature control medium circuit, the medium being divided into a first and a second temperature control medium before reaching the first and the second temperature control circuit section.

The at least one first and the at least one second temperature control section may be part of temperature control circuits of the application separated in a fluid-tight manner, whereby the first and second temperature control media are separate and independent of each other. According to the invention, it can be provided that the at least two surface sections to be temperature-controlled, with which the at least one first and second flow channel is in thermally conductive connection, are in thermally conductive connection with each other, either by the fact that the two surfaces of the at least one first and second flow channel are partial surface sections of the surface section to be temperature-controlled, or by the fact that the two surfaces of the at least one first and second flow channel are, through or around each other, in thermally conductive connection with each other via the object to be temperature-controlled or via an arrangement of a plurality of objects to be temperature-controlled.

Furthermore, it may be provided that the temperature control device according to the invention further comprises at least one first temperature control medium inlet, as well as at least one first distribution channel for connecting at least two first temperature control medium inflows of at least two first flow channels to the at least one first temperature control medium inlet of the device and/or comprise at least one second temperature control medium inlet, as well as at least one second distribution channel for connecting at least two second temperature control medium inflows of at least two second flow channels to the at least one second temperature control medium inlet of the device.

The flow channels, the at least one distribution channel and/or the at least one return flow channel may be formed from a polymeric and/or a metal material.

The counter current temperature control device according to the invention may further comprise at least one first temperature control medium outlet, as well as at least one first return flow collection channel for connecting at least two first temperature control medium outlets of at least two first flow channels to the at least one first temperature control medium outlet of the device and/or comprise at least one second temperature control medium inlet, as well as at least one second return flow collection channel for connecting at least two second temperature control medium outlets of at least two second flow channels to the at least one second temperature control medium outlet of the device.

It can be provided that the at least one first temperature control medium inlet or the first distribution channel is located opposite the at least one first temperature control medium outlet or the first return flow collection channel in a first plane parallel to the first flow direction and the at least one second temperature control medium inlet or the second distribution channel is located opposite the at least one second temperature control medium outlet or the second return flow collection channel in the first plane, wherein the at least one first temperature control medium inlet or the first distribution channel is located opposite to the at least one second temperature control medium outlet or the second return flow collection channel relative to the first plane, and the at least one second temperature control means inlet or the second distribution channel is located opposite the at least one first temperature control medium outlet or the first return flow collection channel relative to the first plane, whereby the flow direction of the temperature control medium in the at least one first flow channel is opposite to that in the at least one second flow channel.

Furthermore, it may be provided that the at least one first and second temperature control section are connected to the temperature control circuit of the application only via one feed and only one return, in which the at least one first temperature control medium inlet of the first temperature control section and the second temperature control medium inlet of the second temperature control section are connected to the temperature control circuit of the application by a common feed, and wherein the at least one first temperature control medium outlet of the first temperature control section and the second control medium outlet of the second temperature control section are connected to the temperature control circuit of the application by a common return.

The above-mentioned embodiment has the effect that, depending on the number of temperature control sections, the temperature control medium is divided into at least one first temperature control medium and at least one second temperature control medium before flowing through the temperature control sections, and after having flown through the temperature control sections, the first and second temperature control media are reintroduced to again form a common temperature control medium in the common return.

According to the invention, it may be provided that a plurality of first and second flow channels is provided, the first and second flow channels being arranged along the objects to be temperature-controlled substantially geometrically parallel to each other, and the first and second flow channels being still being arranged alternately in a common arrangement plane orthogonal to the flow paths.

It may further be provided that a plurality of first and second flow channels is formed, wherein the first flow paths of the flow channels extend substantially parallel to each other and the first flow channels are arranged in a first arrangement plane, wherein the second flow paths of the flow channels extend substantially parallel to each other and the second flow channels are arranged in a second arrangement plane, wherein the first arrangement plane is spaced from the second arrangement plane in the orthogonal direction.

Moreover, it may be provided that a receiving space for arranging at least one object to be conductively temperature-controlled is formed between the respective adjacent first and/or second flow channels arranged in the respective first and/or second arrangement plane, wherein a first flow channel and a second flow channel is in thermal conductive connection with the at least one object to be temperature-controlled.

The object to be temperature-controlled can comprise at least two first and second surface sections to be temperature-controlled, wherein a first flow channel can be designed to be at least partially in thermally conductive connection with the first surface section, and s second flow channel can be designed to be at least partially in thermally conductive connection with the second surface section.

It may be provided that the respective at least directly adjacent first and/or second flow channels, which are arranged in the common arrangement plane or in the respective first and/or second arrangement plane, are designed adjacent to each other or at least at a distance, in the same plane and the same direction, smaller than their flow channel width in order to form a common main temperature control surface for contact with at least one object to be temperature-controlled or at least one arrangement of a plurality of objects to be temperature-controlled.

Moreover, it may be provided that all first and second flow channels in the common arrangement plane or in the respective first and/or second arrangement plane are designed to be directly adjacent to each other in order to form at least one thermally conductive overall temperature control surface for abutment against at least one object to be temperature-controlled or at least one arrangement of a plurality of objects to be temperature-controlled.

It may be provided that the at least one first and/or second flow channel is designed to be flattened in a plane parallel to the flow path in order to form a thermally conductive contact surface form at least one object to be temperature-controlled.

In a counterflow temperature control device according to the invention, the number of first flow channels can be identical to the number of second flow channels, plus-minus one flow channel.

The number of first flow channels and the number of second flow channels may each respectively correspond to the number of rows of the objects arranged in rows along which the flow channels extend, plus-minus one flow channel,
or
the number of first flow channels and the number of second flow channels may be respectively designed corresponding to an integer fraction of the object rows along which the flow channels extend, plus-minus one flow channel,
or
the number of first flow channels and the number of second flow channels may be respectively correspond to an integer multiple of the object rows along which the flow channels extend, plus-minus one flow channel.

According to the invention, it may also be provided that at least the first and/or second flow channels are formed from at least tow layers, wherein at least two layers are formed either from at least two individual parts or at least two partial sections of a part, which are connected to each other, preferably stacked on one another or folded on one another, in partial regions in order to form the plurality of flow channels bounded in a fluid-tight manner with respect to the environment.

The layers may be formed, for example, from substantially flat parts, hereinafter also referred to as flat parts, the surface dimensions of which, at least in one surface direction, are a multiple of the height or thickness dimension, but which nevertheless have a three-dimensional geometry required for the function or can assume such a geometry in operation, for example in order to be able to form the temperature control medium volume with at least the flow channels, or in order represent fastening regions in the form of, for example, ribs or screw domes, in particular when using a shaping manufacturing method such as, for example, metal or plastic injection molding or compression injection molding.

As an alternative, a folded singular/individual layer of a flat sheet material can form the first and/or second flow channel, wherein the layers are connected to each other in partial regions to form the plurality of flow channels bounded in a fluid-tight manner with respect to the environment. In the framework of the present invention, a metal sheet and/or a metal and/or polymer and/or elastomer film can preferably be used as the flat sheet material.

As an alternative, the at least two layers may also be formed from a singular component or flat part manufactured in a shaping manufacturing process, which for example has a more complex three-dimensional geometry, the layers being formed with the component comprising at least one thin flexible region, preferably in the form of a film hinge, via which the component can be folded over. With at least two thin flexible regions, preferably in the form of film hinges, which are arranged such that e.g. a Z-shaped, i.e. alternating folding is possible, at least three layers can be correspondingly realized with one component.

In order to combine the advantages of a flat sheet material with respect to being thin-walled and to thermal conductivity and the advantages of a shaping material with respect to a greater freedom of design, it is particularly preferred to use both materials either via a mixed assembly of flat parts of a flat sheet material in combination with flat parts of a shaping material or to use them as hybrid parts which are formed in some regions from a flat sheet material and a shaping material.

The first and second flow channels may alternatively each be designed as extrusion profiles or immersion molded bodies.

The first and second flow channels and the at least one first and/or the at least one second distribution channel and/or the at least one and/or the at least one second return flow collection channel may be formed by at least three layers joined one above the other in partial regions to form or delimit the individual channels.

The division of the temperature control medium after the common feed into a first and a second temperature control medium may be effected via a first temperature control medium inlet of the first temperature control section and via a second temperature control medium inlet of the second temperature control section, wherein the one first and the one second temperature control medium inlet are located within the assembly formed from the three layers.

The merging of the one first temperature control medium and the one second temperature control medium before the common return flow, may be effected via a first temperature control medium outlet of the first temperature control section and via a second temperature control medium outlet of the second temperature control section, wherein the one first and the one second temperature control medium outlet are located within the assembly formed from the three layers.

The at least two layers or the at least three layers may be formed by flat parts, whose spanned surface dimensions are greater in at least one surface direction than 10 times, preferably greater than 100 times of the wall thickness of the layers or the flat parts, wherein at least the layer or the layers or the flat part or the flat parts are made from a thin-walled, i.e. having a thickness less than 3 mm, preferably less than 1 mm, particularly preferred less than 0.5 mm, metal and/or polymer and/or elastomer thermally conductive material, which face the objects to be temperature-controlled.

At least the layers or flat parts facing the objects to be temperature-controlled may be made from a thin flat sheet material such as, for example, at least one shaped metal sheet and/or a polymer and/or an elastomer and/or a metal film or at least include such a flat sheet material as a part of a composite or hybrid component.

The layers or flat parts averted from the objects to be temperature-controlled may be formed from a thin flat sheet material such as, for example, at least one shaped metal sheet and/or a polymer and/or an elastomer and/or a metal film, or may be made from a metal or polymer molding compound, or be manufactured as a hybrid part formed from a flat sheet material and a molding compound molded to the same.

According to a second aspect, the present invention relates to a battery housing for receiving at least one battery cell comprising a counter current temperature control device according to the first aspect of the invention.

According to a third aspect, the present invention further relates to the usage of a counterflow temperature control device according to the first aspect of the invention for temperature control of electrical components, such as electrical energy storages and/or electrical circuits.

Preferably, the counterflow temperature control device can be used for the temperature control of electrical energy storages in the form of round cells, cuboid prismatic cells or flat, pocket-shaped battery cells, wherein at least one first and one second flow channel is brought into abutment with at least a partial region of an outer wall of the energy storage to be temperature-controlled and/or is at least in thermally conductive connection with the energy storage to be temperature-controlled.

Furthermore, a use for temperature control of energy storages of a stationary application of a terrestrial, sea- or airborne vehicle may be provided according to the invention.

In the following, exemplary embodiments of the counterflow temperature control device according to the invention are explained with reference to the accompanying Figures. The reference numerals are identical across all embodiments so that functional regions of the same or at least a comparable function bear the same reference numeral. If a reference numeral is not described for an embodiment, the designation and function thereof can be found analogously in the description of Figures regarding another embodiment.

### BRIEF DESCRIPTION OF THE DRAWINGS

FIG. 1A shows schematic top plan views on the first and second temperature control sections of a first exemplary embodiment of a counterflow temperature control device in single view;

FIG. 1B shows a schematic top view on the first exemplary embodiment of a counterflow temperature control device comprising a first and a second temperature control section according to FIG. 1A;

FIG. 2A shows perspective views of a first and a second temperature control section of a second exemplary embodiment of a counterflow temperature control device in single view;

FIG. 2B shows a perspective view of the counterflow temperature control device comprising a first and a second temperature control section according to FIG. 2A in combination;

FIG. 2C shows the counterflow temperature control device according to FIGS. 2A and 2B in plan view with objects to be temperature-controlled illustrated in an exemplary manner;

FIG. 3A is a perspective view of a further exemplary embodiment of a counterflow temperature control device according to the invention;

FIG. 3B is a partially disassembled perspective illustration of the components of the counterflow temperature control device according to FIG. 3A;

FIG. 3C shows further sectional and detail views of the counterflow temperature control device of the present invention according to FIGS. 3A and 3B;

FIG. 4A is a perspective view of a further exemplary embodiment of the counterflow temperature control device according to the present invention;

FIG. 4B is a further perspective view of the embodiment of the counterflow temperature control device according to the present invention shown in FIG. 4A;

FIG. 4C is a disassembled perspective illustration of the components of the counterflow temperature control device according to FIG. 4A and FIG. 4B, respectively;

FIG. 4D is another disassembled perspective illustration of the components of the counterflow temperature control device according to FIG. 4A and FIG. 4B, respectively;

FIG. 4E is a top plan view on the counterflow temperature control device in FIGS. 4A and 4B, respectively, and further sectional and detail views;

FIG. 4F is a top plan view on the counterflow temperature control device in FIGS. 4A and 4B, respectively, and further sectional and detail views;

FIG. 4G shows further sectional and detail views of the counterflow temperature control device in FIG. 4A and FIG. 4B, respectively, but with a variant of the feed and return interface connection;

FIG. 4H shows an exemplary arrangement configuration of the counterflow temperature control device in FIG. 4A and FIG. 4B, respectively, and a first arrangement of objects to be temperature-controlled;

FIG. 4I shows another exemplary arrangement configuration of the counterflow temperature control device in FIG. 4A and FIG. 4B, respectively, consisting of a first and a second counterflow temperature control device between which an object arrangement is temperature-controlled;

FIG. 4J shows an exemplary arrangement configuration of the counterflow temperature control device in FIG. 4A and FIG. 4B, respectively, and a first arrangement of objects to be temperature-controlled and a second arrangement of objects to be temperature-controlled;

FIG. 5A is a perspective view of a further exemplary embodiment of the counterflow temperature control device according to the present invention;

FIG. 5B is a disassembled perspective illustration of the components of the counterflow temperature control device according to FIG. 5A;

FIG. 5C is a detail view of the inner layer 43C;

FIG. 5D is a top plan view on the counterflow temperature control device in FIG. 5A with objects to be temperature-controlled shown in an exemplary manner, and further sectional and detail views;

FIG. 5E shows an exemplary detail of an arrangement configuration of the counterflow temperature control device according to FIG. 5A and of an object arrangement to be temperature-controlled;

FIG. 6A is a perspective view of a further exemplary embodiment of the counterflow temperature control device according to the present invention;

FIG. 6B is a top plan view on the counterflow temperature control device in FIG. 6A with objects to be temperature-controlled shown in an exemplary manner, and a further sectional and detail view; and

FIG. 6C shows a side view of the counterflow temperature control device in FIG. 6A, and a further sectional and detail view.

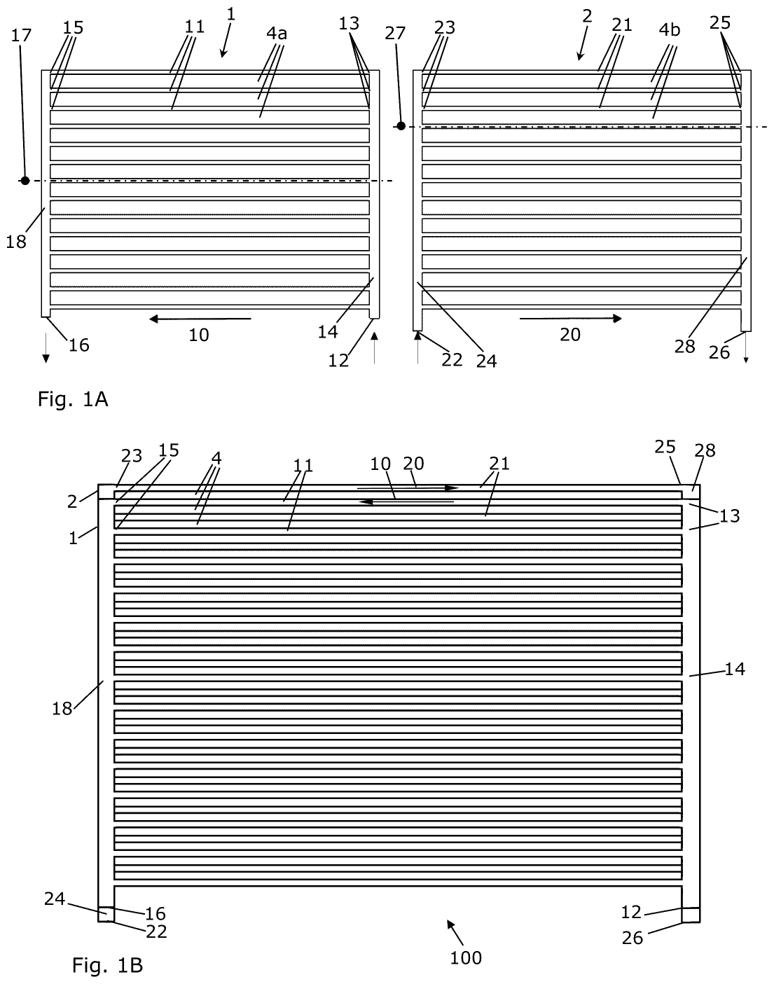

FIG. 1A shows single views of a first temperature control section 1 and of a second temperature control section 2 of a counterflow temperature control device 100 for temperature control of at least one object 3 according to the invention. The counterflow temperature control device 100 comprises a first temperature control section 1, as well as a second temperature control section 2, which are illustrated in single view in FIG. 1A for a better comprehensibility of the realized features. The first temperature control section 1 comprises at least one first flow channel 11. In the embodiment illustrated, the first temperature control section 1 includes the exemplary number of fourteen first flow channels 11 for a temperature control medium to flow through in a first flow direction 10 from a first channel inflow 13 to a first channel outflow 15 along a first flow path 17. The first flow path is illustrated in FIG. 1A as a chain-dotted line bearing the reference numeral 17.

In the following description of the Figures, the objects to be temperature-controlled of any shape are assigned the reference numeral 3, as examples for such objects to be temperature-controlled, reference number 3a denotes a substantially cylindrical object and reference symbol 3b denotes a substantially prismatic object. The objects 3a and 3b are only illustrated as examples and are exemplary for objects 3 to be temperature-controlled of any shape.

The second temperature control section 2 in turn has at least one second flow channel 21, with, in the embodiment illustrated, an exemplary total number of fourteen second flow channels 21 for a second temperature control medium to flow therethrough in a second flow direction 20 from the first channel inflow 23 to an opposite second channel outflow 25 along a second flow path 27. The first flow direction 10 extends substantially opposite to the second flow direction 20, as can be seen in the assembled illustration of the counterflow temperature control device 100 of FIG. 1B.

In the embodiment of FIGS. 1A and 1B illustrated, the counterflow temperature control device 100 further comprises a first temperature control medium inlet 12, as well as a first distribution channel 14 for connection of the plurality of the first temperature control medium inflows 13 to the first temperature control medium inlet 12. The device 100 further comprises a second temperature control medium inlet 22, as well as a second distribution channel 24. In addition, the counterflow temperature control device 100 according to FIGS. 1A and 1B is further formed with a first temperature control medium outlet 16, as well as a first return flow collection channel 18 for connection of the plurality of first temperature control medium outflows 15 to the first temperature control medium outlet 16, as well as a second temperature control medium outlet 26 and a second return flow channel 28 for connection of the plurality of second temperature control medium outflows 25 to the second temperature control medium outlet 26.

In the counterflow temperature control device 100 according to FIGS. 1, the first flow paths 17 of the first flow channels 11 extend parallel to each other, wherein the first flow channels 11 are arranged in a first arrangement plane which extends orthogonal to the first flow paths 17, and wherein the second flow paths 27 of the second flow channels 21 extend substantially parallel to each other and the second flow channels 21 are arranged in a second arrangement plane, with the first and second arrangement planes being oriented orthogonally with respect to each other.

The exemplary embodiment of the counterflow temperature control device 100 according to the invention illustrated in FIG. 1 allows to set up three different arrangement configurations (A, B and C) in combination with the objects 3, as will be discussed in the following to be temperature-controlled

### Arrangement Configuration A:

In the arrangement configuration A, the first and the second arrangement plane of the flow channels 11 and 21 are oriented in parallel to each other and are at the same time spaced in the orthogonal direction. The spacing of the first and second arrangement plane results in a receiving space between the arrangement planes and thus between the first and second flow channels 11 and 21, which receiving space is not illustrated in FIGS. 1, but in which the objects 3 to be temperature-controlled can be arranged. In the arrangement configuration A, the objects 3 to be temperature-controlled are temperature-controlled via two substantially opposite surfaces. For this arrangement configuration, the flow channels 11 and 21 are preferably designed to be wide in the direction of the respective arrangement plane, so that an area percentage as large as possible and thus main temperature control surfaces 42 as large as possible are realized. The wide design of the flow channels 11 and 21 results in a correspondingly small area percentage of the free spaces 4a and 4b between the flow channels 11 and 21. As is particularly preferred, the free spaces 4a and 4b can be omitted in the arrangement configuration A, in which case directly adjacent flow channels 11, 21 are formed per temperature control section.

### Arrangement Configuration B:

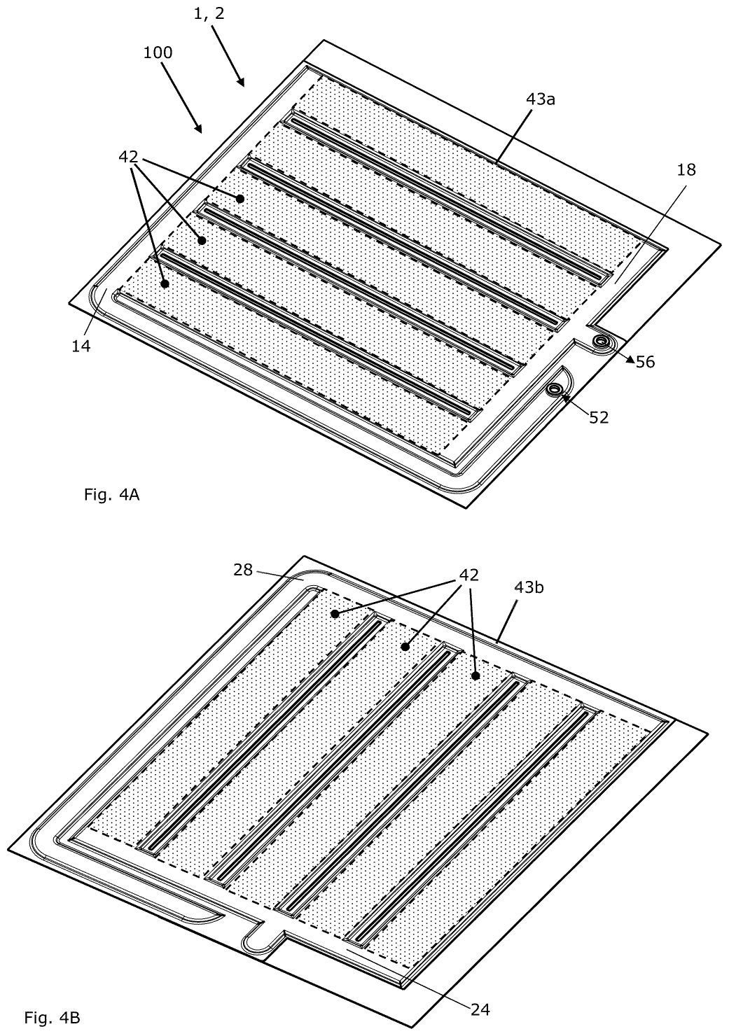

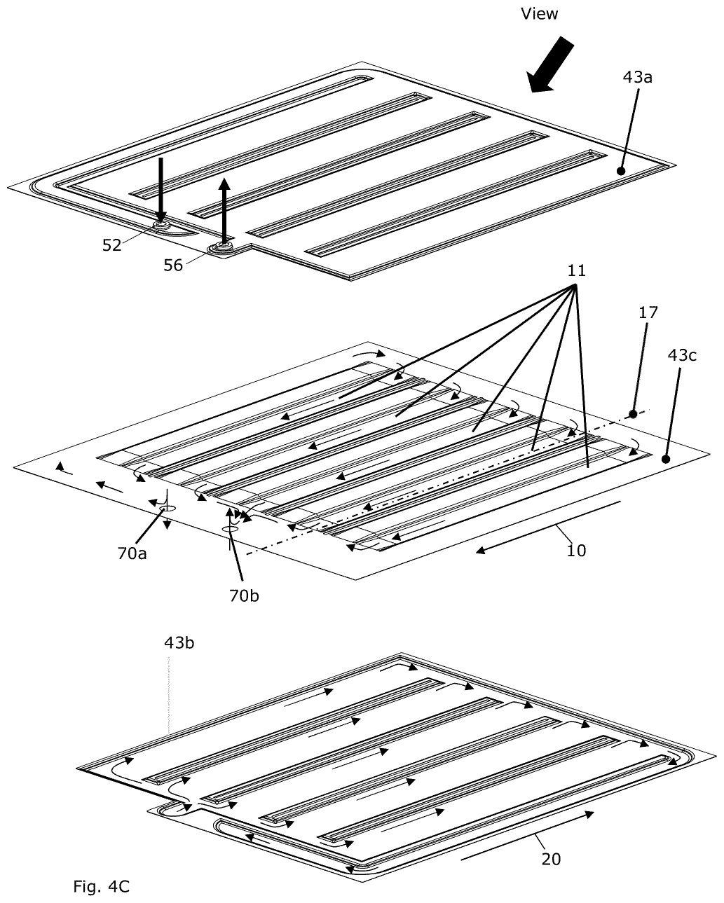

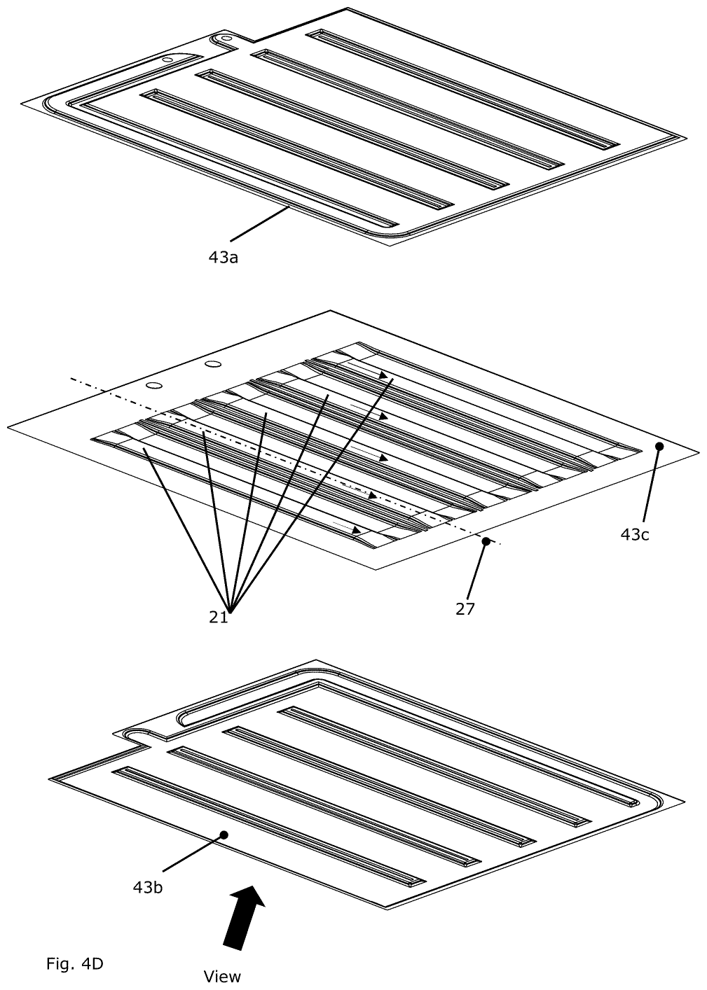

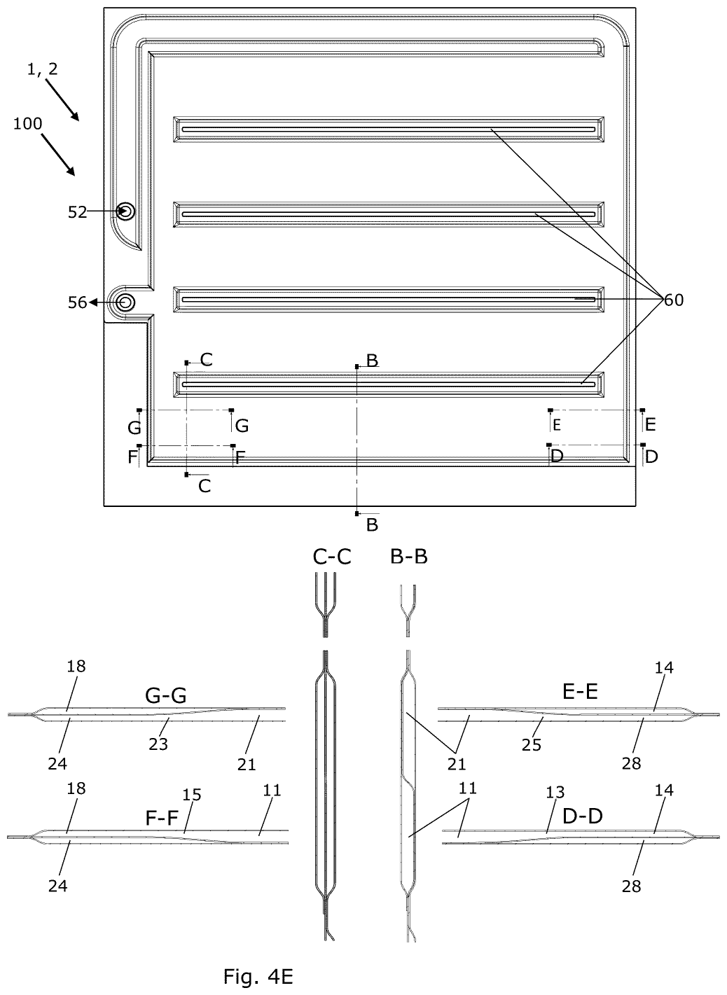

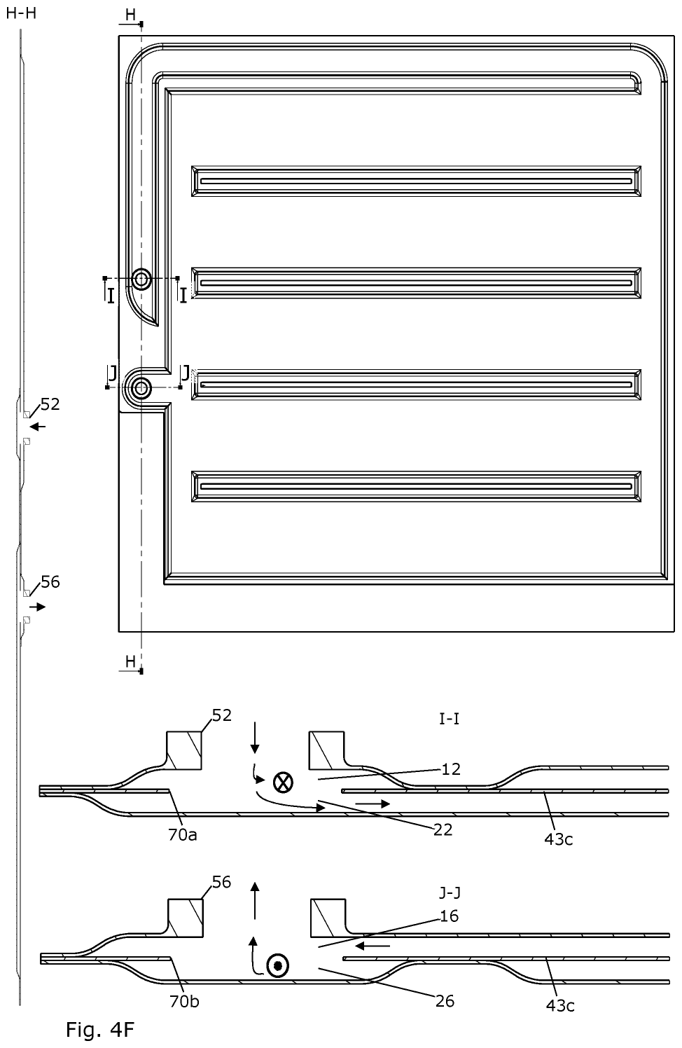

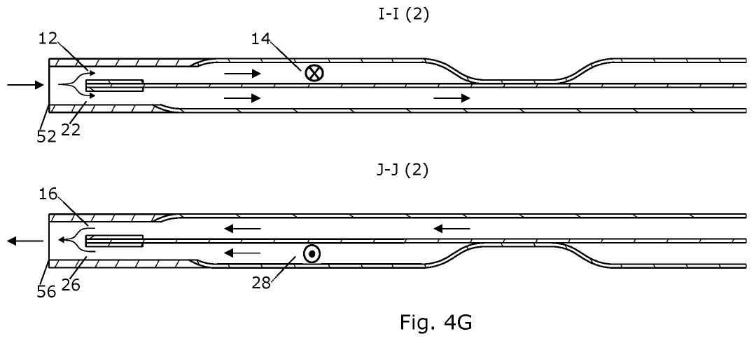

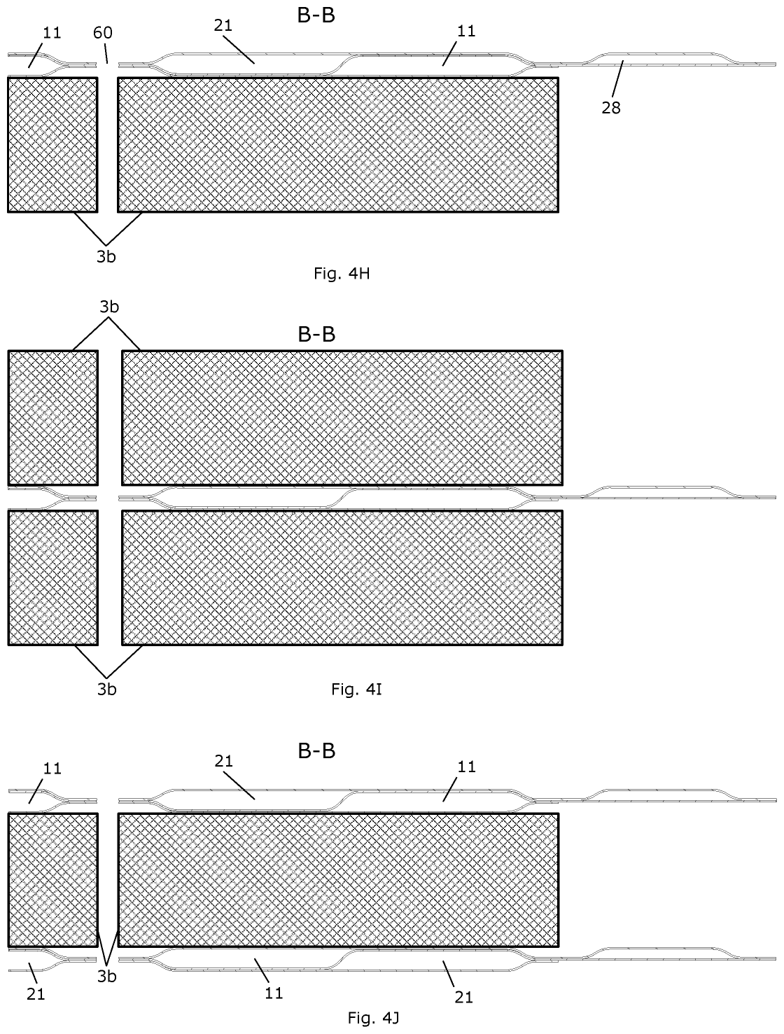

In the arrangement configuration B, the first and second arrangement plan of the flow channels 11 and 21 on one and the same side of the object 3 to be temperature-controlled or on one and the same side of the arrangement of objects 3 to be temperature-controlled are arranged parallel to each other, and the flow channels 11 and 21 are directly or indirectly in thermally conductive contact with the surface or surfaces of the objects 3 or the object arrangement. In the arrangement configuration B, the flow channels 11 and 21 are also preferably designed to be wide in the direction of the arrangement planes, so that an area percentage as large as possible and thus main temperature control surfaces 42 as large as possible are realized. In addition, in this arrangement configuration B, the flow channels 11 are spaced from each other, the spaces between the flow channels 11 themselves are preferably larger than the width of the flow channels 21, so that a thermally conductive connection of the flow channels 21 to the object 3 or the object arrangement to be temperature-controlled is realized via a contact surface which preferably substantially corresponds to the width of the flow channels 21. It is particularly preferred that the flow channels 11 and 21 each have a width smaller than the width of the free spaces 4a and 4b between the flow channels 11 and 21. In this superimposed arrangement of the temperature control sections 1 and 2, it is particularly preferred that at least the contact surfaces of the flow channels 11 and 21 are substantially brought to one plane. For this purpose, the structural design can preferably be such that the flow channels 21 extend within the spacing of the flow channels 11 in the direction of the surface to be temperature-controlled or are sunken, or that at least the flow channels 21 are made from a plastically or elastically deformable material and the contact surfaces of the flow channels 21 are pressed to the same level as the contact surfaces of the flow channels 11, and/or that at least the flow channels 21 are made from a flexible material which is deformed by the hydrostatic pressure of the temperature control medium, and contact surfaces of the flow channels 21 are pressed through the spacings of the flow channels 11 onto the surface to be temperature-controlled or onto surfaces connected to the object(s) 3 to be temperature-controlled in a thermally conductive manner. The arrangement configuration B can also be taken from the illustration of the embodiment in FIG. 4H which is identical in terms of functional principle.

The counterflow temperature control described above in the arrangement configuration B from one side of the object 3 or the object arrangement to be temperature-controlled is analogously also possible from two opposite sides of the object 3 or the object arrangement to be temperature-controlled by arranging a further pair of two temperature control sections 1, 2 with flow channels 11, 21 according to the above description on the opposite side of the object 3 or the object arrangement to be temperature-controlled. In contrast to arrangement configuration A, in this variant of arrangement configuration B, both opposite main temperature control surfaces 42 in thermally conductive connection with the object or objects 3 are respectively counterflow temperature-controlled. This extended arrangement configuration B can also be taken from the illustration of the embodiment in FIG. 4J which is identical in terms of functional principle.

The counterflow temperature control described above in the arrangement configuration B via one side of the at least one first object 3 or the at least one first object arrangement to be temperature-controlled can be extended by at least one second object or at least one second object arrangement to be temperature-controlled, which are in thermally conductive connection with the side of the flow channels 11, 21 that faces away from the first object arrangement. In this variant of the arrangement configuration B, the at least one first object arrangement and the at least one second object arrangement are spaced in parallel to each other and the flow channels 11, 21 are located within the spacing between the first and second object arrangement. Analogously, this configuration can also be extended by a third object arrangement and further object arrangements, which are each arranged on planes parallel to each other and spaced apart from each other in an orthogonal direction and between which flow channels 11, 21 are preferably arranged and connected to the object arrangements in a thermally conductive manner, respectively. This extended arrangement configuration B can also be taken from the illustration of the embodiment in FIG. 4I which is identical in terms of functional principle.

### Arrangement Configuration C:

In the arrangement configuration C, the first and the second arrangement plane 1, 2 of the flow channels 11 and 21 are arranged in parallel, directly adjacent to one another or at a small distance from each other, wherein the flow channels 11 and 21 in this arrangement configuration C preferably have a small width, so that the distances between the flow channels 11 and 21 are each large and free spaces 4a, 4b are formed in each case between the flow channels 11 and 21. In this arrangement configuration, the first flow channels 11 are offset from the second flow channels 21 preferably by about half the distance between the first flow channels 11, so that, as illustrated in the top plan view in FIG. 1B, the free spaces 4a, 4b are mutually divided by the flow channels 11, 21 into two preferably receiving spaces 4 equal in size.

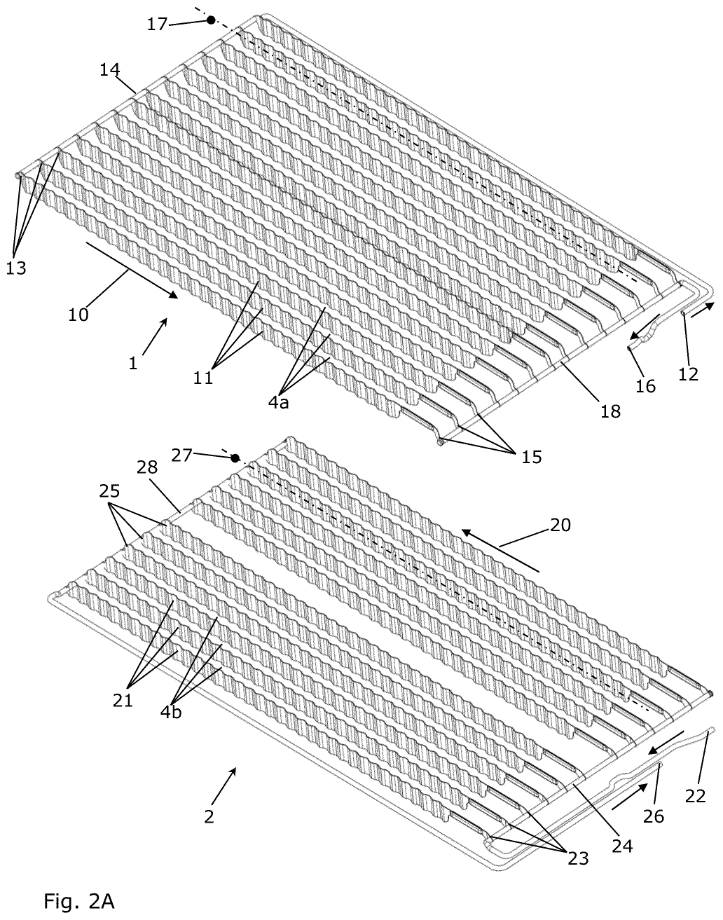

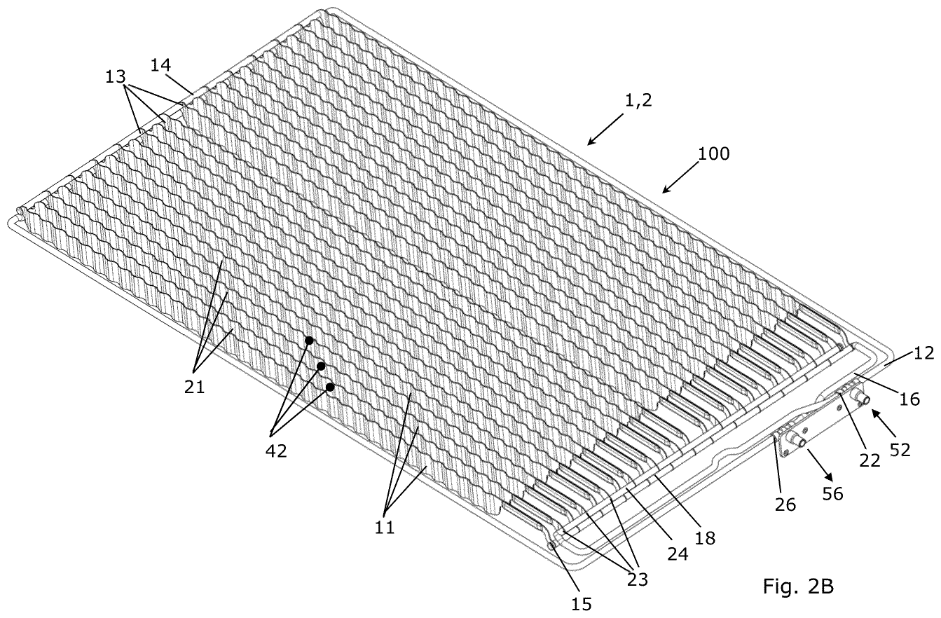

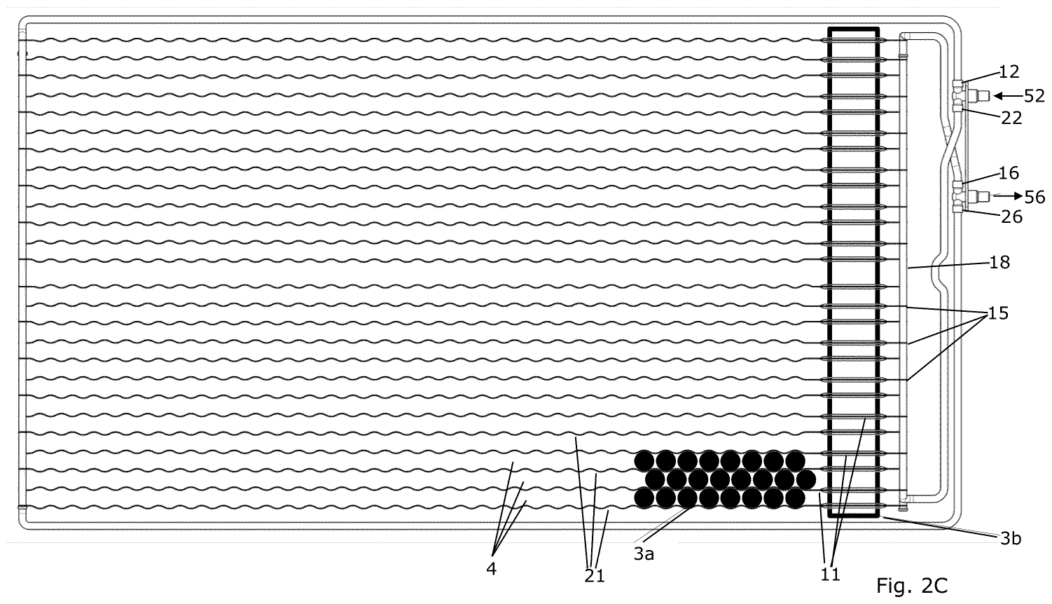

In the arrangement configuration C of the counterflow temperature control device 100 of FIG. 1B, a receiving space 4 is formed between the respective first and second arrangement planes 1, 2 of the respectively adjacent first and second flow channels 11, 21 for the arrangement of at least one object 3 to be conductively temperature-controlled, wherein the at least one object 3 to be temperature-controlled, which is not illustrated in FIGS. 1, comprises at least two first and second surface sections to be temperature-controlled, wherein a first flow channel 11 is at least partially in thermally conductive connection with the second surface section and a second flow channel 21 is at least partially in thermally conductive connection with the second surface section, as can be seen by way of example in FIG. 2C with regard to a further embodiment of a counterflow temperature control device 100 according to the invention.

FIG. 2 show a further exemplary embodiment of the counterflow temperature control device 100 according to the invention. FIG. 2A shows a perspective single view of the first temperature control section 1 formed, as well as of the second temperature control section 2. FIG. 2B shows the counterflow temperature control device 100 according to the invention shown FIG. 2A in combination, and FIG. 2C shows a top plan view of the counterflow temperature control device 100 according to the invention shown in FIGS. 2A and 2B with objects 3 to be temperature-controlled arranged therein in an exemplary manner.

The embodiment of the counterflow temperature control device 100 according to the invention shown in FIG. 2 substantially comprises the features shown in FIGS. 1, in particular according to arrangement configuration C, but the counterflow temperature control device 100 in FIG. 2 differs from the one in FIG. 1 in that the first and second flow channels 11, 21 extend in a common arrangement plane and a receiving space 4 is formed between the respective adjacent first and second flow channels 11, 21 for arranging at least one object 3 to be conductively temperature-controlled or a plurality of objects 3 to be temperature-controlled in the common arrangement plane. The at least directly adjacent first and second flow channels 11, 21 arranged in the common arrangement plane are arranged substantially geometrically parallel to one another along the objects 3 to be temperature-controlled, and the first and second flow channels 11, 21 are also arranged alternately in a common arrangement plane orthogonally to the flow paths.

In the exemplary embodiment according to FIGS. 2, the first and second flow channels 11, 21 are flattened in a plane parallel to the flow paths 17, 27 in order to form thermally conductive main temperature control surfaces 42 for a further object 3b to be conductively temperature-controlled extending over a plurality of flow channels. As can also be seen from FIG. 2, the flow paths 17, 27 of the first and second flow channels 11, 21 are corrugated along the flow path 17, 27 in order to adapt the flow path 17, 27 to the objects 3 to be temperature-controlled which are to be accommodated, as can be seen in FIG. 2C. It is particularly preferred to choose a flexible material for the flow channels 11, 21, whereby the same can adapt to the course of the arrangement of the objects to be temperature-controlled, and whereby, due to the hydrostatic temperature control medium pressure, these also press against the objects 3 and 3b to be temperature-controlled or a surface connected in a thermally conductive manner to the objects to be temperature-controlled without a gap. As can also be seen in FIG. 2C, the first and second flow channels 11, 21 are connected in a thermally conductive manner to surface sections of the at least one object 3 to be temperature-controlled. The at least one object 3 to be temperature-controlled has at least a first surface section to be temperature-controlled and a second surfaces section to be temperature-controlled, wherein a flow channel 11 is at least partially connected to the first surface section in a thermally conductive manner and a second flow channel 21 is at least partially connected to the second surface section in a thermally conductive manner. As can be seen in FIG. 2C, the wave-shaped arrangement of the flow paths 17, 27 of the first and second flow channels 11, 21 allows for a higher packing density of the cylindrical objects 3 to be temperature-controlled on the one hand and increases the first and second partial surface sections to be temperature-controlled. With regard to a simple integration of the counterflow temperature control device 100 into the preferably only one temperature control circuit of the application, in this embodiment, the at least one first distribution channel 14 is flow-connected via the at least one first temperature control medium inlet 12 and the at least one second distribution channel 24 is flow-connected via the at least one second temperature control medium inlet 22 and are fed via a common feed 52. It is particularly preferred in this embodiment that also the at least one first return flow collection channel 18 is flow-connected via the at least one first temperature control medium outlet 16 and the at least one second return flow collection channel 28 is flow-connected via the at least one second temperature control medium outlet 26 and return into the preferably only one temperature control circuit of the application via the at least one common return 56.

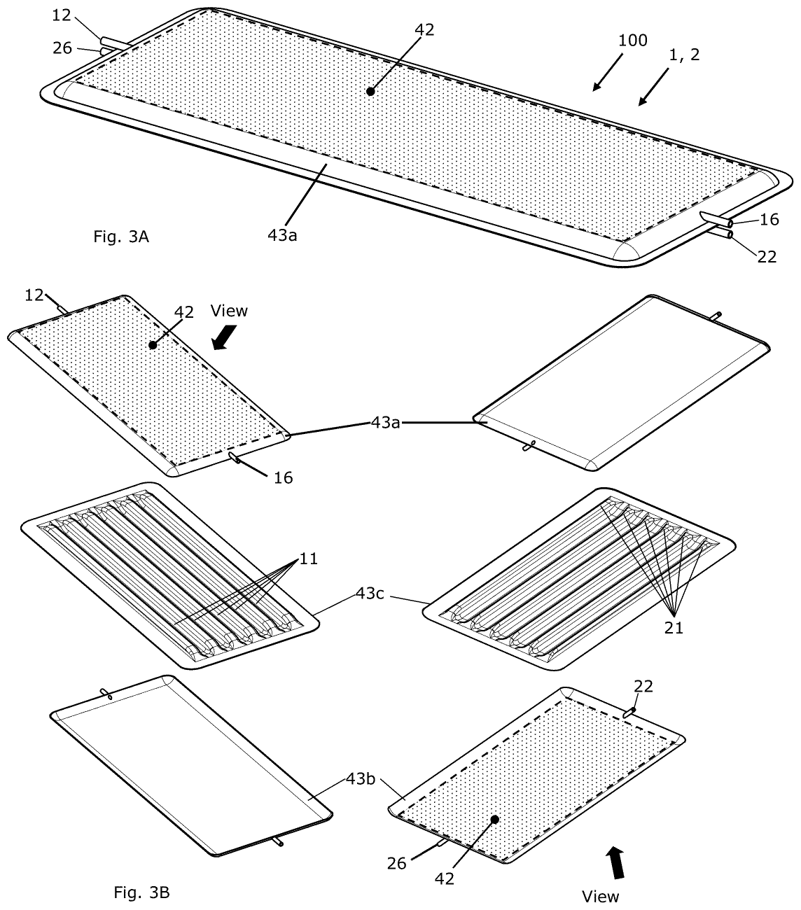

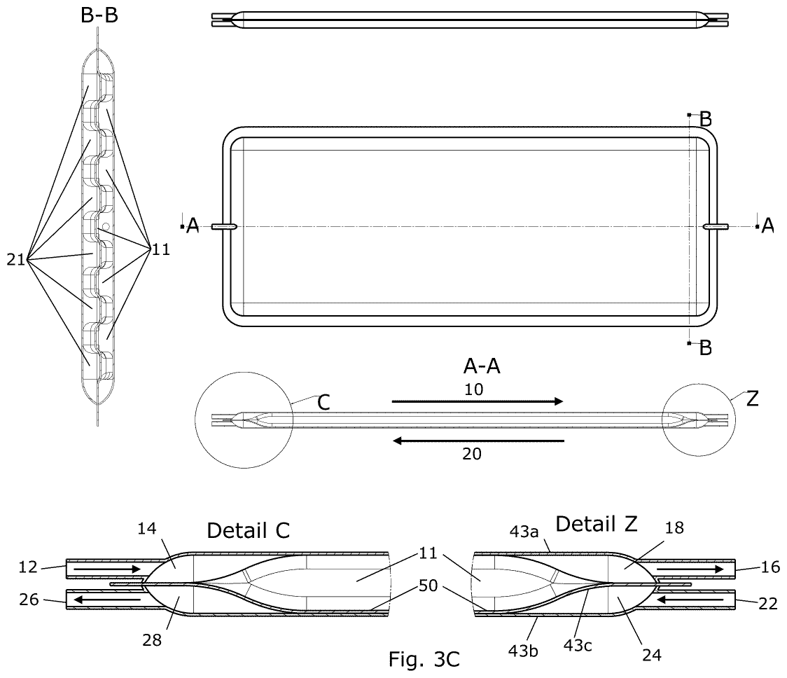

FIGS. 3A-3C illustrate a further alternative embodiment of a counterflow temperature control device 100 according to the invention. With this embodiment, arrangement configurations can be realized in combination with the objects 3 to be temperature-controlled, which correspond to the variants of the arrangement configurations B according to FIG. 1. The main difference between the embodiment of FIG. 3 and the embodiment of FIG. 1 is that the embodiment is formed by a temperature control section 1 and a temperature control section 2, each comprising its own flow channels 11 or 21, its at least one own distribution channel 14 or 24 and its at least one return flow collection channel 18 or 28, whereby they are structurally separate units. In the embodiment according to FIGS. 3A-3C, the first and second flow channels 11, 21, as well as distribution channels 14, 24 and return flow collection channels 18, 28 are structurally integrated into one unit.

The exemplary temperature control device according to FIGS. 3A-3C is formed by at least three flat parts 43a, 43b, 43c, the spanned surface of which preferably corresponds to at least the surface to be temperature-controlled. The flat parts 43a, 43b, 43c may for example be formed from a sheet metal plate. The three flat parts 43a, 43b, 43c are joined circumferentially at the edge region while overlapping, so that an overall volume is enclosed between the outer flat parts 43a, 43b. The overall volume is divided by the central flat part 43c into at least two partial volumes: a first partial volume between the layer 43a and the layer 43c and a second partial volume between the layer 43b and 43c. The first partial volume forms the volume of the at least one first distribution channel 14, the at least two first flow channels 11 and the at least one first return flow channel 18, and the second partial volume forms the volume of the at least one second distribution channel 24, the at least two second flow channels 21 and the at least one second return flow channel 28. To form the flow channels 11, 21 inside the counterflow temperature control device 100, the inner layer 43c is wave-shaped for at least 50% of the spanned surface and is in thermally conductive contact with the layer 43b via at least one wave 50, which is in thermally conductive connection with at least a first object arrangement to be temperature-controlled. Due to the contact of the at least one wave with a layer 43b, the second partial volume is divided in the region of the contact, so that flow channels 21 are formed beside the contact of the wave. The number of flow channels 21 depends on the number of waves of the layer 43c, which are preferably in thermally conductive connection with the layer 43b. The number of flow channels 11 also depends on the number of waves on the opposite side are in preferably thermally conductive contact with the layer 43a. The waves themselves preferably have a meander-shaped or rectangular or trapezoidal contour. The flow channels 11 and 21 are always arranged in turns, i.e. alternately, side by side in a direction of a plane. Upstream of the contact of the wave in the direction of flow, i.e. upstream of the division of the second partial volume, the distribution channel 24 is formed, and downstream of the contact of the wave with the layer 43b, seen in the direction of flow, the return flow collection channel 28. It is particularly preferred that also the waves approaching layer 43a are also connected thereto, on the one hand to increase the mechanical stability of the temperature control device and on the other hand to form a complete fluidic delimitation among the flow channels 11 in a direction transverse to their direction of flow. It is particularly preferred that the thermally conductive contacting of the waves of the inner layer 43c to both the layer 43b and 43a is also connected in a thermally conductive manner to the first layer 43b for counterflow temperature control of a first object arrangement and is connected in a thermally conductive manner to the layer 43a or counterflow temperature control of a second object arrangement.

The counterflow temperature control via layer 43b and/or layer 43a of one or a plurality of object arrangements is performed during the flow of a first temperature control medium through the counterflow temperature control device 100 starting from at least one first temperature control medium inlet 12 and the flow of a second temperature control medium starting from at least one second temperature control medium inlet 22, wherein then first temperature control medium flows into the at least one first distribution channel 14 and is distributed from there to the at least two first flow channels 11 and flows therethrough, the first temperature control medium being collected again via the at least one first return flow collection channel 18 after having flown through the first flow channels 11, and the at least one first return flow collection channel 18 finally forwards the first temperature control medium to the temperature control medium outlet 16 connected to the temperature control circuit of the application.

When flowing through the first flow channels 11 for temperature control of a first object arrangement connected to the layer 43b in a thermally conductive manner, the thermal energy, in case of cooling, flows, preferably substantially in the region of the at least one main temperature control surface 42, starting from the first object arrangement through the wall thickness of layer 43b into the wall thickness of layer 43c and the layer 43c and finally transfers the thermal energy to the first temperature control medium in the first flow channels 11. As described above, the first flow channels 11 are arranged alternately in a direction of a plane next to the second flow channels 21.

The second temperature control medium flows through the second flow channels 21 in a direction opposite the first flow channels 11. When flowing through the first flow channels 21 for temperature control of a first object arrangement connected to the layer 43b in a thermally conductive manner, the thermal energy, in case of cooling, flows from the first object arrangement through the wall thickness of layer 43b and the same transfers the thermal energy to the second temperature control medium in the second flow channels 21. The thermal energy does not have to flow through the wall thickness of layer 43c on the way from the first object arrangement on the side of layer 43b to the second temperature control medium, since the amplitude regions of the waves of layer 43c, which delimit the flow channels 21, abut against layer 43a, preferably against the main temperature control surfaces 42 thereof, and not against layer 43b.

In the case of temperature control of at least one second object arrangement in thermally conductive connection to layer 43a, the reverse is true correspondingly. Here, the thermal energy has to flow from the second object arrangement to the second temperature control medium in the flow channels 21 through the wall thickness of layer 43a and the wall thickness of layer 43c, whereas the thermal energy to the first temperature control medium in the flow channels 11 only has to penetrate the wall thickness of layer 43a.

In a particularly preferred embodiment not illustrated, the inner layer 43c has passages within the contact surface to layer 43a and/or layer 43b, via which the temperature control medium is in direct contact with the inner surfaces of layer 43a or 43b, and the thermal energy from and to the temperature control medium only has to penetrate layer 43 a or 43b of the counterflow temperature control device. In a further particularly preferred embodiment not illustrated, layer 43c only has separating webs in the region of the flow channels 11 and 21, which separate the flow channels 11, 21 from each other.

In particular in the thermally conductive contact regions with layer 43b or 43a, layer 43c is preferably made of a thermally conductive metal and/or polymer material and/or of a thin material with a wall thickness of less than 3 mm, particularly preferred a material of less than 0.5 mm in wall thickness.

In the embodiment illustrated, the first and second flow channels 11, 21 are arranged in a common arrangement plane and the directly adjacent first and second flow channels 11, 21 are formed directly adjacent to each other, wherein at least one or two opposite thermally conductive temperature control surfaces 42 are designed for contact with at least one object 3 to be temperature-controlled.

The exemplary embodiment of the device according to FIGS. 3A-3C is particularly advantageous, since this embodiment of the counterflow temperature control device 100 is formed substantially only by three shaped sheet metal parts or three films or thin-walled polymer components or a three-part composite structure of the mentioned parts or materials, the temperature control surface 42 is formed by two identical outer lower and upper shells 43a and 43b and a three-dimensionally wave-shaped central sheet metal-like or film-like layer 43c. It may also be provided according to the invention to provide a different number of shaped sheet metal parts or films to form the device.

As in the embodiment according to FIGS. 3, in the exemplary embodiment according to FIGS. 4, all illustrated parts of the counterflow temperature control device 100 are structurally integrated into one unit, i.e. the first temperature control section 1, which, inter alia, comprises the first flow channels 11, and the second temperature control section 2, which, inter alia, comprises the second flow channels 21, are combined in one assembly. The same arrangement configurations B and C (see FIGS. 4H, 4I, 4J) can be realized with the embodiment according to FIG. 4 as with the embodiment according to FIG. 3.

In contrast to the embodiment of FIGS. 3, the at least one first temperature control medium inlet 12 of the first temperature control section 1 and the second temperature control medium inlet 22 of the second temperature control section 2 are connected to a common feed 52 of the temperature control circuit; and the at least one first temperature control medium outlet 16 of the first temperature control section 1 and the second temperature control medium outlet 26 of the second temperature control section 2 are connected to a common return 56 of the temperature control circuit.

It follows from this that, in contrast to the embodiment according to FIGS. 3, the embodiment according to FIG. 4 only particularly preferably comprises a feed 52 and a return 56 as outer temperature control medium interfaces. The integration effort for integrating the embodiment of FIG. 4 into only one temperature control circuit with only one available interface to a feed 52 and a return 56 of the application is thus significantly reduced compared to the embodiment of FIG. 3.

FIG. 4A shows a perspective view of the side of layer 43a, then feed 52 and the return 56, wherein, in a manner not illustrated, the feed 52 and the return 56 may also be located on different sides or also be located parallel to the plane of the counterflow temperature control device 100.

FIG. 4B shows a perspective view of the side of layer 43b.

FIG. 4C shows a perspective exploded view of the side of layers 43a, 43c and 43b, on which the feed 52 and the return 56 are located, as an example. The inner layer 43c divides the overall volume into a first partial volume between layer 43a and the inner layer 43c and into a second partial volume between layers 43b and 43c, wherein the first partial volume analogously comprises the first temperature control section 1 and the second partial volume comprises the second temperature control section 2, wherein the first and second temperature control sections 1, 2, in contrast to the embodiment of FIG. 1 or 2, form an integrative unit in FIG. 4. In FIG. 4C, the first flow channels 11 can be seen, which are fed by the first distribution channel 14 and open into the return flow collection channel 18 after the flow of medium therethrough, which return flow collection channel collects the temperature control medium and directs it to the return 56 of the counterflow temperature control device 100. The flow directions of the temperature control medium are illustrated by arrows in the individual illustrations in FIG. 4C.

FIG. 4D shows a perspective exploded view of the side of layers 43a, 43c and 43b which is opposite to the side having the feed 52 and the return 56 in this exemplary embodiment according to FIG. 4. In the viewing direction of FIG. 4D, the second flow channels 21 can be seen on the inner layer 43c, which are located between or formed by the inner layer 43c and layer 43b. The flow channels 21 are fed by the second distribution channel 24 and, after having flown through the flow channels 21, the second temperature control medium flows into the second return flow collection channel 28 which collects the second temperature control medium and directs it to the return 56 of the counterflow temperature control device 100. These flow paths inside the counterflow temperature control device 100 can be seen in FIGS. 4A to 4E, including the sectional views in FIG. 4E.

Another difference to the embodiment according to FIG. 3 is that the embodiment according to FIG. 4 may have openings 60 across the extending surface, as illustrated in FIG. 4E. On the one hand, these openings 60 enable a one-sided direct mounting of the counterflow temperature control device 100 to parts, not illustrated, of the temperature control application and/or the object arrangement to be temperature-controlled itself, for example by means of an interlock or a screw connection or welding of the edge regions of the openings 60.

On the other hand, the openings 60 also allow the counterflow temperature control device 100 to be maintained in shape or be pressed in a defined manner on both sides against the surface to be temperature-controlled of the at least one object arrangement, in that connection elements may be implemented within the surface of the counterflow temperature control device 100, which establish a direct or indirect connection between the at least one surface to be temperature-controlled of the at least one object arrangement and at least one further, opposite surface of the application, for example of a housing or a second object arrangement. Consequently, given this exemplary mounting state, the counterflow temperature control device 100 is held between the surface to be temperature-controlled on one side and a further surface on the opposite side of the counterflow temperature control, wherein the opposite surfaces are connected through connectors via the openings 60.

The two possible mounting states described by way of example each may be used to ensure the thermally conductive contact to the at least one object arrangement to be temperature-controlled over the entire surface 42 to be temperature-controlled, even with larger counterflow temperature control devices 100. When a thin-walled and/or flexible material, e.g. a thin sheet metal or a film, is used at least in the region of the flow channels, an additional pressing of layer 43a and/or 43b against the at least one surface to be temperature-controlled can be realized via the hydrostatic pressure of the temperature control medium.

FIG. 4F shows the sections H-H, I-I and J-J through the feed 52 and the return 56. As a matter of example, in this embodiment, the first temperature control medium inlet 12 of the first temperature control section 1 and also the second temperature control medium inlet 22 of the second temperature control section 2 are located in the region of the feed 52. One of the tow or both temperature control medium inlets 12, 22 may also be spaced from the feed 52 in an embodiment not illustrated. In the views in FIG. 4F, the flow paths are again indicated by arrows, with the symbol⊗ indicating that a flow path is directed into the image plane, while the symbol ⊙ illustrates that a flow is directed out of the image plane.

After the temperature control medium has flown into the feed 52, in this exemplary embodiment, the temperature control medium is divided into a first temperature control medium via the first temperature control medium inlet 12 to the first temperature control section 1 and into a second temperature control medium via the second temperature control medium inlet 22 to the second temperature control section 2, the first temperature control medium inlet 12 and the second temperature control medium inlet 22 being fluidically connected to the feed 52 such that both temperature control sections 1, 2 are fluidically connected in parallel to each other.

Since the first temperature control section 1 and the second temperature control section 2 are on different sides of the inner layer 43c, but the preferably only one feed 52 in this embodiment is located on only one side of the counterflow temperature control device 100, a throughflow opening 70a is formed in the inner layer 43c as a temperature control medium inlet 22 to the second temperature control section 2 facing away from the feed 52.

Section J-J in FIG. 4F shows how the first and second temperature control media from the two temperature control section 1,2, coming from the return flow collection channels 18, 28, are combined again upstream of the feed 56 via the first and second temperature control medium outlets 16, 26, wherein the second temperature control medium outlet 26 is realized by the throughflow opening 70b and the first temperature control medium outlet 16 corresponds to the opening of the return 56 through which the first and second temperature control media are discharged after their merging.

FIG. 4G shows further sectional and detail views of the counterflow temperature control device 100 in FIG. 4A and FIG. 4B, respectively, but with a variant of the feed and return interface connection. In this variant of the feed and return interface connection, the feed 52 and the return 56 are connected at the edge of the counterflow temperature control device 100 via layers 43a and 43b or the supply 52 and the return 56 are formed by the layers 43a and 43b themselves. The embodiment according to FIG. 4 thus offers the advantage, depending on the structural conditions of the application, of arranging the at least one feed 52 and the at least one return 56 at different positions and having them point in different directions.

FIG. 4H shows the section B-B of FIG. 4E in an exemplary arrangement configuration with an object arrangement 3b to be temperature-controlled and a section of a part of a further object arrangement 3b. It is particularly preferred that each object arrangement 3b is in thermally conductive connection with at least one first and one second flow channel 11 and 21. If an object arrangement is formed by a plurality of objects 3b, preferably all objects 3b are in thermally conductive connection to one first and one second flow channel 11 and 21, respectively. For this purpose, it is particularly preferred to design the common width of a first and a second flow channel 11, 21 such that, if possible, the same do not significantly exceed the dimension of the individual object 3b to be temperature-controlled in the transverse direction to the flow direction of the flow channels 11, 21, or preferably the common paired widths of a first and a second flow channel 11, 21 correspond to only a fraction of the dimension of the individual object 3b to be temperature-controlled in the transverse direction to the flow direction of the flow channels 11, 21, so that preferably a plurality of pairings of a first and a second flow channel 11 and 21 can be connected in a thermally conductive manner to the individual objects, respectively.

FIG. 4I shows the section B-B of FIG. 4E in an exemplary extended arrangement configuration, in which, compared to the illustration in FIG. 4H, a second counterflow temperature control device 100 is connected in a thermally conductive manner on the opposite side to the object arrangement or arrangements to be temperature-controlled. This enables the realization of a more uniform temperature distribution within the volume of the object arrangement. In this arrangement, it is particularly preferred for an optimal uniform temperature distribution to have the opposite flow channels 11, 21 of the first and the second counterflow temperature control device 100 be flown through in opposite directions, as illustrated in FIG. 4I by the opposite different reference 21 and 11 as well as 11 and 21.

FIG. 4J shows the section B-B of FIG. 4E in an exemplary extended arrangement configuration, in which, compared to the illustration in FIG. 4H, a second object arrangement and a section of a part of a further second object arrangement are connected on the opposite side of the object arrangements to one of the counterflow temperature control devices 100. In this arrangement configuration, two arrangement planes of object arrangements to be temperature-controlled can be temperature-controlled at the same time with only counterflow temperature control device 100.

The functional principle of the preferred embodiment according to FIG. 4 with regard to the temperature control of the at least one object arrangement to be temperature-controlled corresponds to the embodiment according to FIG. 3 and can be taken from the same.

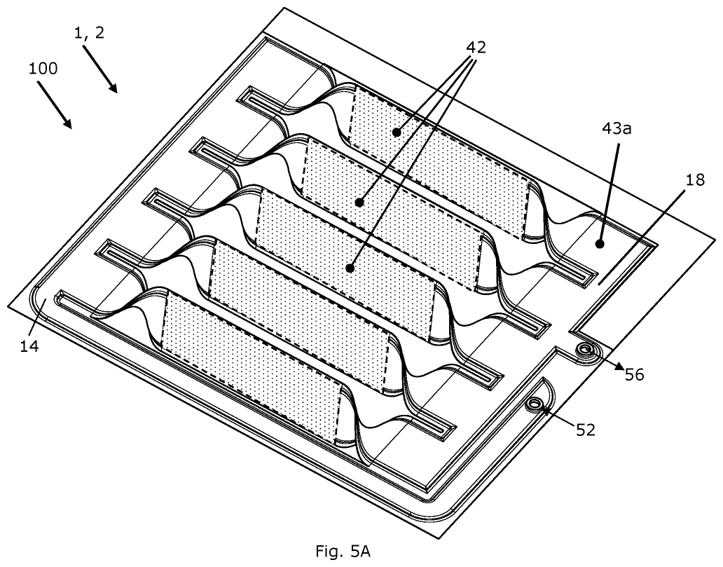

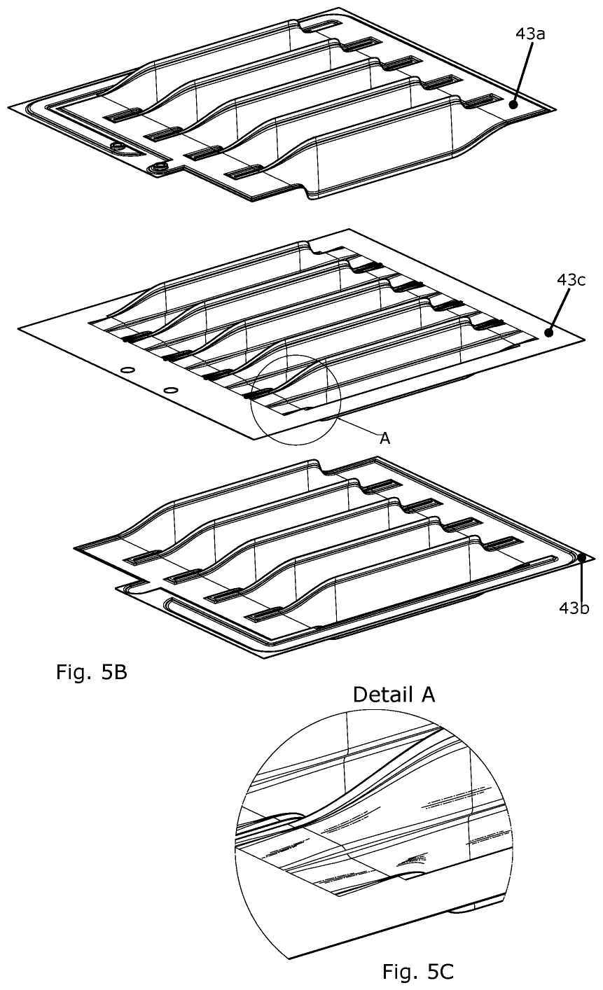

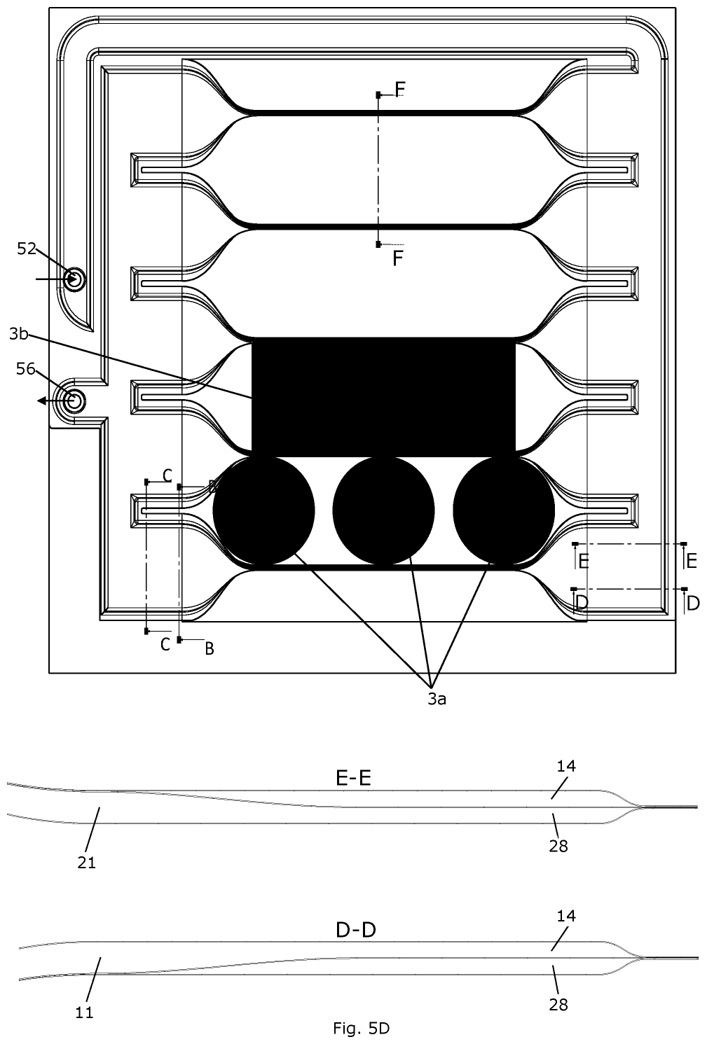

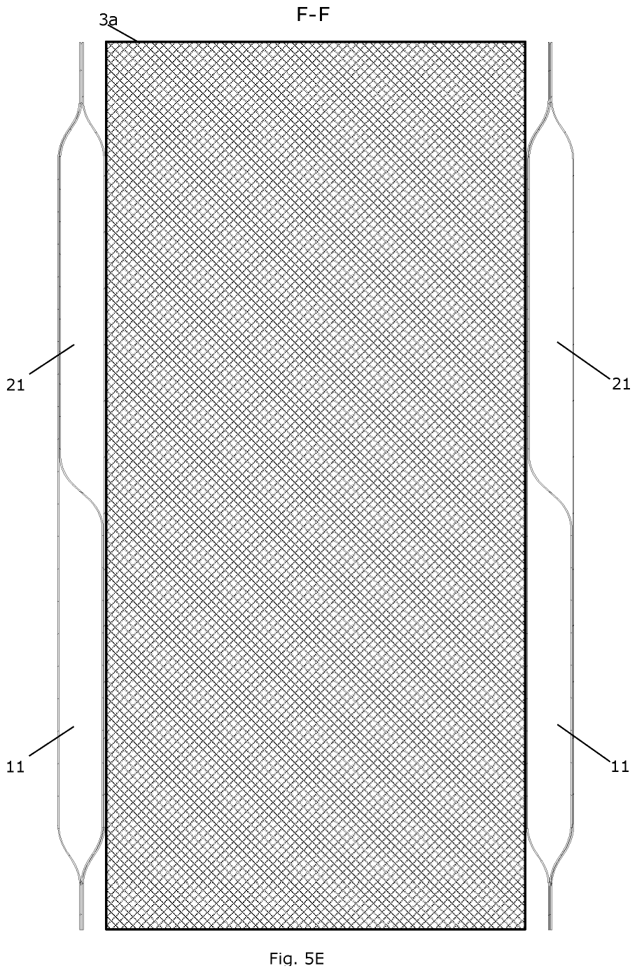

FIGS. 5A to 5E show an embodiment which in structure and function corresponds to the embodiment in FIGS. 4, however, with the difference that this embodiment is designed for the “arrangement configuration” described above with regard to FIGS. 1, in which the side faces of the objects 3 to be temperature-controlled are temperature-controlled. In order to temperature-control the side faces, a first and a second flow channel 11, 21 are each twisted in pairs by about 90° at their first channel inflow 13 and their second channel outflow 25, as well as their second channel inflow 23 and their first channel outflow 15, so that these extend perpendicular to the plane of the counterflow temperature control device 100 and thus create receiving spaces for objects or object arrangements 3, 3b to be temperature-controlled, as illustrated in FIG. 5D.

FIG. 5E shows the section of FIG. 5D through a receiving space with an object or object arrangement 3, 3b to be temperature-controlled. In this section, the object or object arrangement 3, 3b to be temperature-controlled is temperature-controlled on two opposite sides.

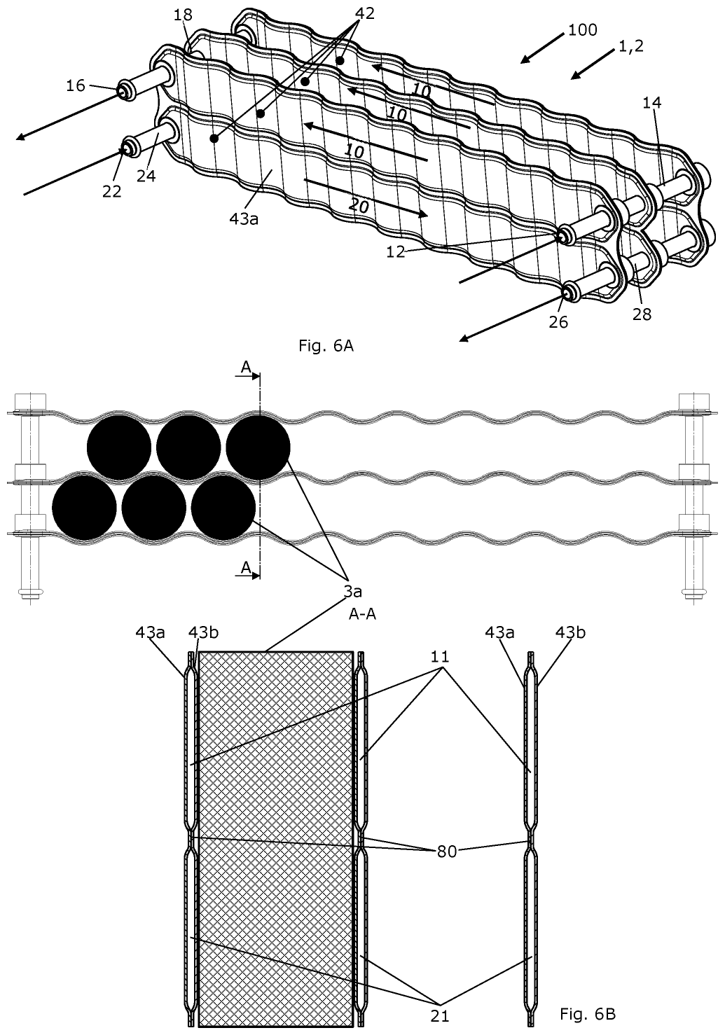

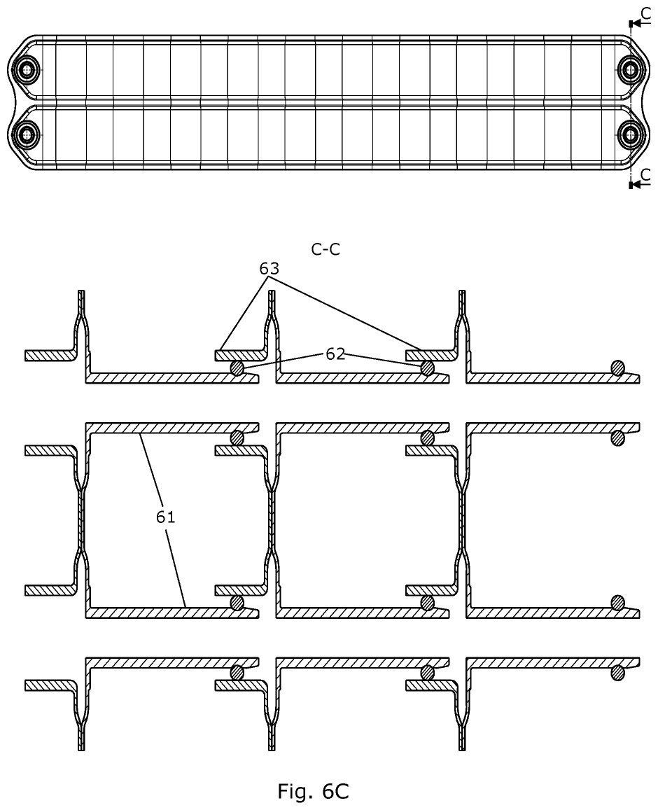

The embodiments of the counterflow temperature control device 100 illustrated in FIG. 6 is, like the embodiment of FIGS. 5, designed for the arrangement configuration C, however, with the difference that it can be composed of several modular units, wherein at least one modular assembly is required to form the counterflow temperature control device 100. Each modular assembly comprises one first and one second temperature control section 1, 2. The temperature control sections 1, 2 in turn each comprise at least a first and a second flow channel 11, 21, to which at least a first and a second distribution channel 14, 24 and at least a first and a second return flow collection channel 18, 28 are fluidically connected. The individual assemblies can be connected to one another via their first and second distribution channels 14, 24 and first and second return flow collection channels 18, 28 in the case of a larger object arrangement to be temperature-controlled, comprising a plurality of objects 3 arranged in rows, as a result of which an extended common first distribution channel 14, an extended common second distribution channel 24, an extended common first return flow collection channel 18 and an extended common second return flow collection channel 28 are produced in each case in accordance with the number of connected assemblies.

FIG. 6C shows a section through the elongated common first distribution channel 14 and through the elongated common second return flow collection channel 28, which represents the connections of the individual distribution channels and return flow collection channels. The sealing of the connections between the distribution channels and return flow collection channels of the interconnected assemblies is particularly preferably realized by means of sealing elements 62, preferably in the form of elastomer seals or adhesive seals or a welded seal. A plug-in connection is particularly preferred, in which a distribution channel or return flow collection channel is plugged into or onto a receiving opening 63 of a further assembly, which is fluidically connected to the distribution channel or return flow collection channel of the further assembly.

FIG. 6B shows an example of how the objects to be temperature-controlled, arranged in rows, are received by the counterflow temperature control device 100, in that they are arranged within the distances of the flow channels of the individual assemblies and are in thermally-conductive contact with the flow channels 11, 21.

Section A-A of FIG. 6B shows the cross-section of the flow channels 11, 21. In this particularly preferred embodiment, the flow channels 11, 21 are formed by two layers 43a, 43b which are fluid-tightly connected to one another at the edge and which are additionally connected at least once, preferably approximately halfway, and this at least one additional connection 80 forms the fluidic separation between the first and second temperature control sections 1, 2 as an essentially linear connection 80. It is also possible to realize more than two temperature control sections 1, 2 by using additional linear connections 80.

In other words, the at least one first and the at least one second flow channel 11, 21 are structurally integrated in one and the same assembly.

In a further particularly preferred embodiment, not shown, the flow channels 11, 21 of each assembly are manufactured in one piece, at least in partial areas viewed over the cross-section, using an extrusion molding process or an injection molding process or an extrusion process and consist of a metal and/or polymer film material or a metal and/or polymer flat sheet material or thin-walled molded material.

What is claimed is:

1. A counterflow temperature control device for the temperature control of at least one object, comprising:
at least one first temperature control section including at least one first flow channel for a temperature control medium to flow through in a first flow direction from a first channel inflow to a first channel outflow along a first flow path;
at least one second temperature control section including at least one second flow channel for a second temperature control medium to flow therethrough in a second flow direction from a second channel inflow to an opposite second channel outflow along a second flow path;
wherein the first flow direction extends substantially opposite to the second flow direction; and
wherein the at least one first and second flow channel are in thermally conductive connection with the at least one object to be temperature-controlled.

2. The counterflow temperature control device of claim 1, wherein the thermally-conductive connection between the at least one object to be temperature-controlled and the at least one first flow channel and the at least one second flow channel is made either by direct surface contact of the at least one first flow channel and the at least one second flow channel on the surface of the at least one object to be temperature-controlled, and/or indirectly via a thermally conductive medium between the surface of the at least one object to be temperature-controlled and the surface or surfaces of the at least one first flow channel and the at least one second flow channel.

3. The counterflow temperature control device of claim 2, wherein the thermally conductive medium is at least one of a thermally conductive gap-filling mass, a thermally conductive layer, a thermally conductive film, a thermally conductive plate comprising a metal sheet or a polymer material, and/or the at least one object to be temperature-controlled, wherein the at least one object to be temperature-controlled ensures the thermal conduction between adjacent objects and the at least one first flow channel and the at least one second flow channel.

4. The counterflow temperature control device of claim 1, further comprising at least one first temperature control medium inlet and at least one first distribution channel for connecting at least two first temperature control medium inflows to the at least one first temperature control medium inlet; and/or further comprising at least one temperature control medium inlet as well as at least one second distribution channel for connecting at least two second temperature control medium inflows to the at least one second temperature control medium inlet.

5. The counterflow temperature control device of claim 1, further comprising at least one first temperature control medium outlet and at least one first return flow collection channel for connecting at least two first temperature control medium outflows to the at least one first temperature control medium outlet; and/or further comprising at least one temperature control medium outlet as well as at least one second return flow collection channel for connecting at least two second temperature control medium outflows to the at least one second temperature control medium inlet of the device.

6. The counterflow temperature control device of claim 4,
wherein the at least one first temperature control medium inlet and/or the first distribution channel is formed opposite the at least one first temperature control medium outlet and/or the first return flow collection channel in a first plane parallel to the first flow direction;
wherein the at least one second temperature control medium inlet and/or the second distribution channel is formed opposite to the at least one second temperature control medium outlet and/or the second return flow collecting channel in the first plane; and
wherein the at least one first temperature control medium inlet and/or the first distribution channel is located opposite to the at least one second temperature control medium outlet and/or the at least one second return flow collecting channel relative to the first plane and the at least one second temperature control medium inlet and/or the at least one second distribution channel is located opposite to the at least one first temperature control medium outlet or the first return flow collecting channel relative to the first plane, whereby the temperature control medium in the at least one first flow channel flows in the opposite direction to the at least one second flow channel.

7. The counterflow temperature control device of claim 1,
wherein the at least one first and second temperature control sections are connected to the temperature control circuit of the application only via one inlet and only via one return;
wherein the at least one first temperature control medium inlet of the first temperature control section and the second temperature control medium inlet of the second temperature control section are connected to the temperature control circuit of the application by a common feed; and
wherein the at least one first temperature control medium inlet of the first temperature control section and the second temperature control medium inlet of the second temperature control section are connected to the temperature control circuit of the application by a common return.

8. The counterflow temperature control device of claim 1, comprising a plurality of first and second flow channels, the first and second flow channels being arranged along the objects to be temperature-controlled substantially geometrically parallel to each other, and the first and second flow channels being arranged alternately in a common arrangement plane orthogonal to the first and second flow paths.

9. The counterflow temperature control device of claim 1, comprising a plurality of first and second flow channels; wherein the first flow paths of the first flow channels extend substantially parallel to each other and the first flow channels are arranged in a first arrangement plane, wherein the second flow paths of the second flow channels extend substantially parallel to each other and the second flow channels are arranged in a second arrangement plane, with the first arrangement plane being spaced from the second arrangement plane in the orthogonal direction.

10. The counterflow temperature control device of claim 8, wherein a receiving space for arranging at least one object to be conductively temperature-controlled is formed between the respective adjacent first and second flow channels arranged in the common arrangement plane or the respective first and/or second arrangement plane, wherein a first flow channel and a second flow channel is in thermal conductive connection with at least one object to be temperature-controlled.

11. The counterflow temperature control device of claim 9, wherein the respective at least directly adjacent first and/or second flow channels, which are arranged in the common arrangement plane or in the respective first and/or second arrangement plane, are designed adjacent to each other or at least at a distance, in the same plane and the same direction, smaller than their flow channel width in order to form a common main temperature control surface for contact with at least one object to be temperature-controlled.

12. The counterflow temperature control device of claim 1, wherein at least one first and/or second flow channel is designed to be flattened in a plane parallel to the first and second flow paths, for forming a common thermally conductive main temperature control surface for at least one object to be conductively temperature-controlled.

13. The counterflow temperature control device of claim 1, wherein at least the first and/or second flow channels are formed from at least two layers, wherein the at least two layers are formed either from at least two individual parts or at least two partial sections of a part, which are connected to each other, preferably stacked on one another or folded on one another, in partial regions in order to form the flow channels bounded in a fluid-tight manner with respect to the environment.

14. The counterflow temperature control device of claim 1, wherein the first and second flow channels and the at least one first and/or the at least one second distribution channel and/or the at least one and/or the at least one second return flow collection channel are formed by at least three layers joined one above the other in partial regions to form or delimit the individual channels.

15. The counterflow temperature control device of claim 13, wherein the temperature control medium is divided into a first and a second temperature control medium after the common inlet via a first temperature control medium inlet of the first temperature control section and via a second temperature control medium inlet of the second temperature control section, wherein the one first and the one second temperature control medium inlet are located within the assembly formed from the three layers, and/or the one first temperature control medium and the one second temperature control medium are merged upstream of the common return via a first temperature control medium outlet of the first temperature control section and via a second temperature control medium outlet of the second temperature control section, the one first and the one second temperature control medium outlet being located within the assembly formed from the three layers.

16. The counterflow temperature control device of claim 13, wherein the at least two layers or the at least three layers are formed by at least one flat part, whose spanned surface dimensions are greater in at least one surface direction than 10 times, preferably greater than 100 times of the wall thickness of the layers or the flat parts, wherein at least the layer or the layers or the flat part or the flat parts are made from a thin-walled, metal and/or polymer and/or elastomer thermally conductive material, which face objects to be temperature-controlled.

17. The counterflow temperature control device of claim 13, wherein at least the layers or flat parts facing objects to be temperature-controlled consist of a thin flat sheet material such as at least one shaped metal sheet or/and a polymer or/and elastomer or/and metal film or contain at least one such flat sheet material as a component of a composite or hybrid component, and wherein the layers or flat parts facing away from the objects to be temperature-controlled consist of a thin flat sheet material such as, for example, at least one shaped metal sheet or/and a polymer or/and elastomer or/and metal film, or is made of a metallic or polymeric molding compound, or is made as a hybrid component from a flat sheet material and a molding compound molded onto it.

18. A battery housing for accommodating at least one battery cell, comprising a counterflow temperature control device according to claim 1.

19. A usage of a counterflow temperature control device according to claim 1 for the temperature control of electrical components, electrical energy storages and/or electrical circuits.

20. The usage of claim 19, for the temperature control of electrical energy storages in the form of round cells, cuboid prismatic cells or flat, pocket-shaped battery cells, wherein at least one of the first and one second flow channels is brought into abutment with at least a partial region of an outer wall of the electrical energy storages to be temperature-controlled and/or is at least in thermally conductive connection with the electrical energy storages to be temperature-controlled.

21. The usage of claim 19, for the temperature control of electrical energy storages of a stationary application or a motor vehicle, an aircraft or a ship.
